(19) United States
(12) Patent Application Publication
(10) Pub. No.: US 2004/0041088 A1
(43) Pub. Date: Mar. 4, 2004

(54) Digital CMOS sensor

(76) Inventor: Shu Fen Chen, Taichung (TW)

Correspondence Address: SHU FEN CHEN, P.O.BOX 2103, Taichung, TW

(21) Appl. No.: 10/228,751

(22) Filed: Aug. 27, 2002

(51) Int. Cl. H01J 5/02; H01L 27/00; H04N 1/024

(52) U.S. Cl. 250/239; 250/208.1; 358/513

(57) ABSTRACT

A digital CMOS sensor including a chip. A periphery of the chip has a lead frame connecting with the lead of the chip. A color filtering layer is directly vapor deposited on the chip and the lead frame for filtering specific frequency of optical wave and comparing the optical wave.

### BACKGROUND OF THE INVENTION

A present invention is related to a digital CMOS sensor in which a color filtering layer is directly vapor deposited on a chip to shorten light path and reduce the volume. In addition, the filtering layer serves to prevent the chip, metallic lead and lead frame from being oxidized.

A digital image technique has been widely applied to image shooting instruments such as digital camera, image scanner, etc. FIG. 6 shows the digital image lens combination of the digital camera. A CMOS sensor 61 is disposed on a circuit board 6. The CMOS sensor 61 has a chip 62. A lens seat 7 is disposed above the CMOS sensor 61. The lens seat 7 has a focusing lens 71 for focusing the image onto the chip 62 of the CMOS sensor 61.

Through the lens, the image signal is sent by the chip 62 to a digital signal processor (DSP) for converting the analog signal into digital signal. The digital signal is provided for a microprocessor for color recovery operation such as zooming, automatic exposure and white balance. The chip 62 of the CMOS sensor 61 is relatively sensitive to infrared ray and red light. In order to achieve more lively color of the image and avoid bias of the color of the image, a filtering lens 72 is disposed between the focusing lens 71 and the CMOS sensor 61. The filtering lens 72 is formed of a glass piece on which a color filtering layer 73 is deposited. The filtering layer 73 serves to filter and compare Ming blue, Oriental red, yellow, green (auxiliary color filter) and red, green, blue (original color filter) light to regulate the shot picture and achieve better image and color.

However, the filtering lens 72 will elongate the light path so that the volume of the digital image lens combination cannot be reduced. As shown in FIG. 7, the filtering lens 72 will refract the light beam so that the light beam cannot be projected to the image sensing area 621 of the chip 62 of the CMOS sensor 61. Therefore, it is necessary to increase the distance between the position of the focusing lens 71 and the chip 62 so as to project the light beam onto the image sensing area 621. Accordingly, the length of the digital image lens combination will be elongated. This makes impossible to apply such digital image lens combination to various minitype digital image instruments.

Furthermore, as shown in FIG. 8, the chip 62 of the CMOS sensor 61 is made of metallic material and the lead frame 622 connecting with the lead of the chip 62 is also metal-made. Therefore, a problem of oxidization exists. Although the CMOS sensor has been packaged, the humidity in the air will still result in oxidization of the chip, lead and lead frame. This will affect the image quality.

### SUMMARY OF THE INVENTION

It is therefore a primary object of the present invention to provide a digital CMOS sensor in which a color filtering layer is directly vapor deposited on the chip. When applied to the digital image lens combination of a digital image instrument, it is unnecessary to further dispose a filtering lens. Therefore, the total volume of the digital image lens combination can be reduced, whereby the digital CMOS sensor can be applied to a small-size digital image instrument.

It is a further object of the present invention to provide the above digital CMOS sensor in which the filtering layer vapor deposited on the chip of the CMOS sensor is also able to prevent the chip, metallic lead and lead frame from being oxidized.

According to the above objects, the digital CMOS sensor of the present invention has a chip on which a color filtering layer is vapor deposited for filtering specific frequency of optical wave and comparing the optical wave.

The present invention can be best understood through the following description and accompanying drawings wherein:

### BRIEF DESCRIPTION OF THE DRAWINGS

FIG. 1 is a sectional view showing that the present invention is applied to a digital image lens of a digital camera;

FIG. 2 shows that a filtering layer is vapor deposited on the chip of the present invention;

FIG. 3 is a sectional view showing that the present invention is directly disposed on a circuit board;

FIG. 4 shows a second embodiment of the present invention, in which a filtering layer is first vapor deposited on the crystal lattice;

FIG. 5 shows that after cut, the CMOS sensor of the second embodiment of the present invention has a filtering layer;

FIG. 6 is a sectional view showing that a conventional CMOS sensor is applied to a digital image lens of a digital camera;

FIG. 7 shows that the light path of the conventional CMOS sensor is elongated; and

FIG. 8 is a front view of the conventional CMOS sensor.

### DETAILED DESCRIPTION OF THE PREFERRED EMBODIMENTS

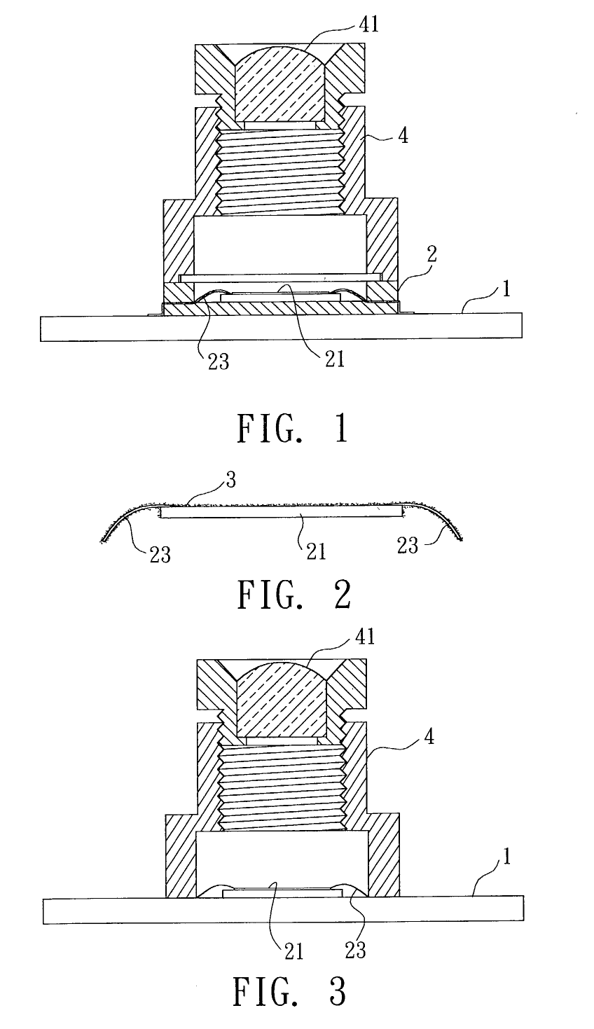

Please refer to FIGS. 1 and 2. The present invention is related to a digital CMOS sensor. For easy illustration, a digital image lens combination applicable to digital camera is exemplified. The digital image lens combination has a CMOS sensor 2 disposed on a circuit board 1. The CMOS sensor 2 includes a chip 21 having an image sensing area 22. The periphery of the chip 21 has a lead frame 23 connecting with the lead of the chip 21 for connecting with the circuit of the circuit board 1. A lens seat 4 is disposed above the CMOS sensor 2. The lens seat 4 has a focusing lens 41 for focusing the image onto the image sensing area 22 of the chip 21.

By way of vapor deposition, a filtering layer 3 is deposited on the surface of the CMOS sensor 2 and the lead frame 23. The filtering layer 3 has a color filtering material for filtering specific frequency of optical wave and comparing the optical wave.

The color filtering layer 3 is vapor deposited on the CMOS sensor 2 so that it is unnecessary to further dispose a color filtering lens for filtering specific frequency of optical wave and comparing the optical wave. Therefore, the total volume of the digital image lens combination can be reduced. This makes it possible to apply the digital image lens combination to a small-size digital image device.

Moreover, the filtering layer 3 is vapor deposited on the surface of the chip 21 of the CMOS sensor 2 and the lead frame 23 to achieve filtering effect. In addition, the filtering layer 3 serves to prevent the metallic chip 21, metallic lead and lead frame 23 in the CMOS sensor 2 from being oxidized due to humidity in the air.

Especially, referring to FIG. 3, in the case that the CMOS sensor 2 is directly disposed on the circuit board 1 without packaging, there is more possibility of contact of the chip 21 and lead frame 23 with the air. Therefore, the chip 21 and lead frame 23 will be more deeply affected by the humidity. However, the filtering layer 3 vapor deposited on the chip 21 of the CMOS sensor 2 and the lead frame 23 is able to prevent the metallic chip 21, metallic lead and lead frame 23 in the CMOS sensor 2 from being oxidized.

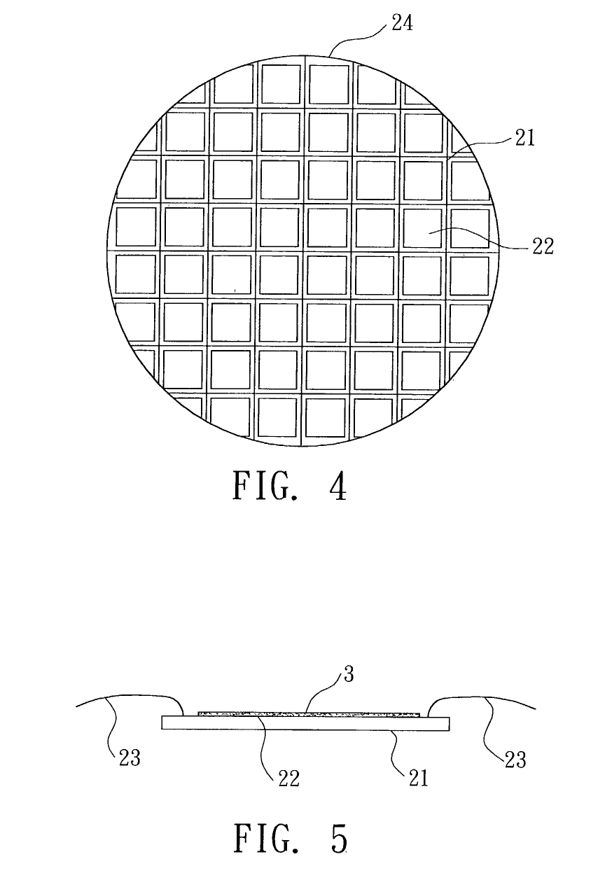

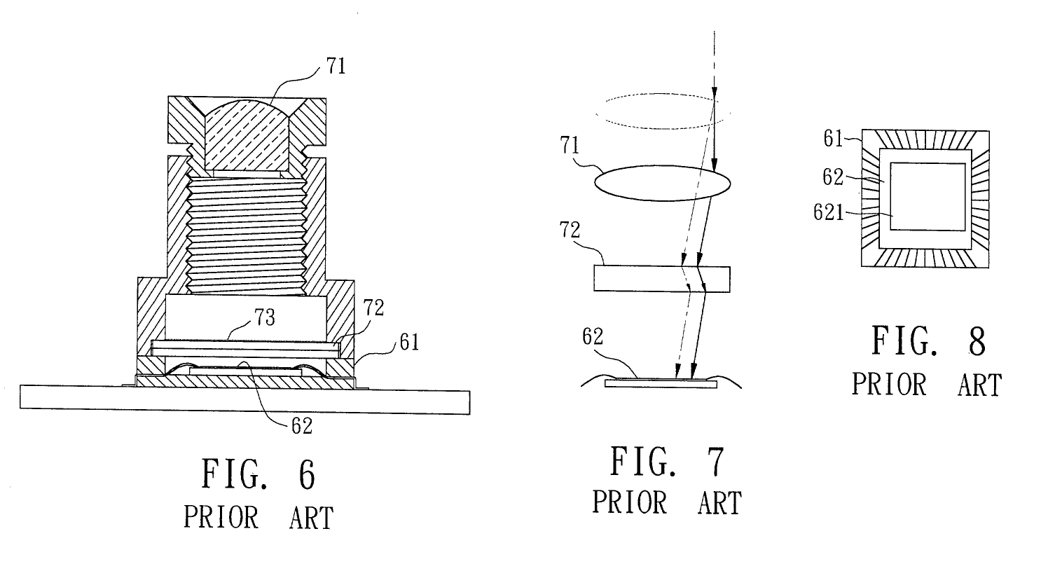

FIGS. 4 and 5 show a second embodiment of the present invention, in which the chip 21 of the CMOS sensor 2 is a crystal lattice 24 without cutting and the filtering layer 3 is vapor deposited on the crystal lattice 24. By means of masking technique, the filtering layer 3 can be vapor deposited on the image sensing area 22 of each chip 21. After cut, the chip 21 has the filtering layer 3. This saves the manufacturers from troublesome respective vapor deposition procedures after packaged so that the manufacturing cost is lowered.

The above embodiments are only used to illustrate the present invention, not intended to limit the scope thereof. Many modifications of the above embodiments can be made without departing from the spirit of the present invention.

What is claimed is:

1. A digital CMOS sensor comprising a chip, a periphery of the chip having a lead frame connecting with the lead of the chip, a color filtering layer being directly vapor deposited on the chip and the lead frame for filtering specific frequency of optical wave and comparing the optical wave.

2. A digital CMOS sensor comprising a chip on which the color filtering layer being directly vapor deposited for filtering specific frequency of optical wave and comparing the optical wave.

3. The digital CMOS sensor as claimed in claim 2, wherein the filtering layer is vapor deposited on an image sensing area of the chip.
